(19) United States
(12) Patent Application Publication
(10) Pub. No.: US 2025/0079796 A1
(43) Pub. Date: Mar. 6, 2025

(54) HCG TUNABLE VCSEL WITH ELECTRICAL AND OPTICAL CONFINEMENT VIA ETCHED POST

(71) Applicant: Bandwidth10, LTD., Berkeley, CA (US)

(72) Inventors: Carlos F. R. Mateus, Berkeley, CA (US); Christopher Chase, Berkeley, CA (US); Michael Y. Huang, Berkeley, CA (US); Chuanshun Cao, Berkeley, CA (US); Dalila Ellafi, Berkeley, CA (US); Neelanjan Bandyopadhyay, Berkeley, CA (US); Carl V. Ford, Berkeley, CA (US); Kai Hui, Berkeley, CA (US); D. Philip Worland, Berkeley, CA (US)

(21) Appl. No.: 18/111,902

(22) Filed: Feb. 21, 2023

(51) Int. Cl. H01S 5/183

(52) U.S. Cl. CPC H01S 5/18325

(57) ABSTRACT

A VCSEL epitaxial structure includes an etched post between an active region and a sacrificial layer. Aa regrowth of sacrificial layer and HCG layer are around the etched post. providing a fully epitaxial grown tunable VCSEL with a small cavity volume, lateral electrical current and optical confinement. The etched post and regrowth provide lateral current and optical confinement, small volume and increased efficiency for more demanding applications, such as very high-speed modulation and coherent communication.

### BACKGROUND

### Field the Invention

This invention related to HCG tunable VCSEL's, and more particularly to HCG tunable VCSEL with electrical and optical confinement via etched post.

### Brief Description of the Related Art

Vertical-cavity surface emitting lasers have been fabricated using selective oxidation to form a current aperture under a top monolithic distributed Bragg reflector mirror are reported. Large cross-sectional area lasers (259 μm2) exhibit threshold current densities of 150 A/cm2 per quantum well and record low threshold voltage of 1.33 V. Smaller lasers (36 μm2) possess threshold currents of 900 μA with maximum output powers greater than 1 mW. The record performance of these oxidized vertical-cavity lasers arises from the low mirror series resistance and very efficient current injection into the active region. Choquette, K. D.; Schneider, R. P.; Lear, K. L.; Geib, K. M.: ‘Low threshold voltage vertical-cavity lasers fabricated by selective oxidation’, Electronics Letters, 1994, 30, (24), p. 2043-2044, DOI: 10.1049/e1:19941421

Vertical-cavity electrically driven lasers have been created with three GaInAs quantum wells and diameters of several μm exhibit room temperature pulsed current thresholds as low as 1·3 mA with 958 nm output wavelength. J. L. Jewell, A. Scherer, S. L. McCall, Y. H. Lee, S. J. Walker, J. P. Harbison, and L. T. Florez, “Low threshold electrically-pumped vertical-cavity surface-emitting micro-lasers,” Optics News 15(12), 10-11 (1989)

VCSEL's have been created with buried heterostructures. As a non-limiting example, a first buried active region vertical cavity surface-emitting laser diodes have been fabricated using in situ dry etching and molecular beam epitaxial regrowth. The laser emission of the etched/regrown devices persists over a greater current range and exhibit maximum output powers larger than air-post lasers. The lasers are anisotropically etched into the lower monolithic distributed Bragg reflector using an electron cyclotron resonance SiCl4 plasma etch. After transfer in ultra-high vacuum, epitaxial AlGaAs current blocking layers are regrown around the etched mesas. Polycrystalline deposition on the Si02 mask is removed by reactive ion etching to allow electrical contact and top surface emission. The etched/regrown laser characteristics demonstrate efficient current confinement and low thermal impedance. The vacuum integrated processing described here offers the prospect of further device performance enhancements and greater functionality. K. D. Choquette, M. Hong, R. S. Freund, J. P. Mannaerts, R. C. Wetzel and R. E. Leibenguth, “Vertical-cavity surface-emitting laser diodes fabricated by in situ dry etching and molecular beam epitaxial regrowth,” in IEEE Photonics Technology Letters, vol. 5, no. 3, pp. 284-287, March 1993, doi: 10.1109/68.205613

To improve the performance of long-wavelength VCSEL's a study of tunnel junctions has been conducted for current injection and confinement. The introduction of a tunnel junction in long-wavelength VCSELs can substantially improve the current injection scheme, because an n-type material is utilized in the p-side region by inserting a tunnel junction. Long-wavelength lasers were fabricated with a tunnel junction formed by metalorganic chemical vapor deposition (MOCVD) using tertiarybutylphosphine (TBP) and tertiarybutylarsine (TBAs), and confirmed the current homogenization effect. Another proposed current confinement structure is by means of a simple fabrication process using a tunnel junction, i.e., the automatically formed tunneling aperture (AFTA). The AFTA has a tunnel junction aperture and can be formed automatically during electrode thermal annealing. Condition of the AFTA was investigated by varying the annealing temperature and time. Ortsiefer, Markus & Shau, Robert & Böhm, Gerhard & Köhler, Fabian & Abstreiter, Gerhard & Amann, Markus-Christian. (2000). Low-resistance InGa (Al)As Tunnel Junctions for Long Wavelength Vertical-cavity Surface-emitting Lasers. Japanese Journal of Applied Physics. 39. 1727-1729. 10.1143/JJAP.39.1727.

Optical lateral confinement in a VCSEL also plays an important role in improving its efficiency. The larger the overlap in between optical field and electrical current the more efficient the VCSEL will be. Current confinement along an aperture is a “must have” in VCSELs—lateral optical confinement is a more relaxed requirement (efficiency related). Some VCSEL designs for electrical current confinement, such as selective oxide aperture and buried tunnel junction (BTJ), also provide optical confinement due to the creation of a step index.

Oxide apertures are feasible only for short wavelength VCSELs, approximately up to 1060 nm, which are manufactured in the GaAs base system. This system allows Ga and Al atoms to be interchangeable in the lattice as AlAs, GaAs, and intermediary combinations of AlGaAs are lattice matched. High Al content in epitaxial layers (>90%) allows for selective oxidation (Al2O3) and creation of electrical apertures, as oxide is not electrically conductive. Such apertures preserve AlGaAs material in the center and the difference in index in between AlGaAs and Al2O3 also provides optical confinement (see Choquette 1994).

Long wavelength VCSELs (above 1.3 um, inclusive) do not have a material system which allows for reliable selective oxidation, mainly due to low quality oxides obtained from selective oxidation. These VCSELs have been using ion implantation as an alternative for current confinement in monolithically manufactured VCSELs. A similar effect can be achieved with buried tunnel junction (BTJ, see Ortsiefer 2000), if regrowth material around tunnel junction aperture has smaller index of refraction than the material in the tunnel junction (see Amann 2000).

Even though BTJ can be a better approach for current confinement, the process requires either long regrowth or wafer bonding techniques. Regrowth or bonding interfaces can bring reliability issues. Ion implanted VCSELs are monolithic and also provide the mesa good current confinement, but not optical confinement.

Some other design approaches which provide both electrical and optical confinement include buried heterostructures (see Choquette 1993) and etched air-post (see Jewel 1989).

The simplest way to transversely define the VCSEL cavity for both electrical and optical confinement is the etched air-post approach. Dry etch techniques, such as reactive ion etching or inductive coupled plasma etching can define small diameter air-posts with smooth side walls. A small diameter can define low active volume and thus small threshold currents and high modulation bandwidths.

### SUMMARY

An object of the present invention is to provide a VCSEL with an epitaxial structure that includes an etched post between an active region and a sacrificial layer.

Another object of the present invention is to provide a VCSEL with a regrowth of a sacrificial layer and HCG layer around an etched post.

Yet another object of the present invention is to provide a fully epitaxial grown tunable VCSEL with a cavity volume of no more than 50 cubic micrometers, lateral electrical current and optical confinement, and thus, increased efficiency.

These and other objects of the present invention are achieved in a VCSEL epitaxial structure with an etched post between an active region and a sacrificial layer. A regrowth of sacrificial layer and HCG layer is around the etched post. This provides a fully epitaxial grown tunable VCSEL with a cavity volume of no more than 50 cubic micrometers, lateral electrical current and optical confinement. The etched post and regrowth provide lateral current and optical confinement, small volume and increased efficiency for more demanding applications, such as very high-speed modulation and coherent communication.

### BRIEF DESCRIPTION OF THE DRAWINGS

FIGS. 1-10 illustrate one embodiment of a VCSEL of the present invention.

FIGS. 11A and 11B illustrate cross sections and top views of a first growth of the present invention.

FIGS. 12A and 12B illustrate cross sections and top views of ion implantation of the present invention.

FIGS. 13A and 13B illustrate cross sections and top views of a mesa etch of the present invention.

FIGS. 14A and 14B illustrate cross sections and top views of ALD wall protection for further selective etch on release, reliability, of the present invention.

FIGS. 15A and 15B illustrate cross sections and top views of InP growth of the present invention.

FIGS. 16A and 16B illustrate cross sections and top views of the HCG layer of the present invention.

FIGS. 17A and 17B illustrate cross sections and top views of the HCG/MEMS litho/dry Etch of the present invention.

FIGS. 18A and 18B illustrate cross sections and top views of the MO-MEMs anchors, of the present invention.

FIGS. 19A and 19B illustrate cross sections and top views of the second mesa etch, M1 access of the present invention.

FIGS. 20A and 20B illustrate cross sections and top views of the second mesa etch, M1 deposit, of the present invention.

FIGS. 21A and 21B illustrate cross sections and top views of the M1 cut of the present invention.

FIGS. 22 illustrates cross sections and top views of the M1 cut of the present invention.

FIGS. 23 illustrates one embodiment of a release.

FIGS. 24-29 illustrate an example of experimental data.

### DETAILED DESCRIPTION

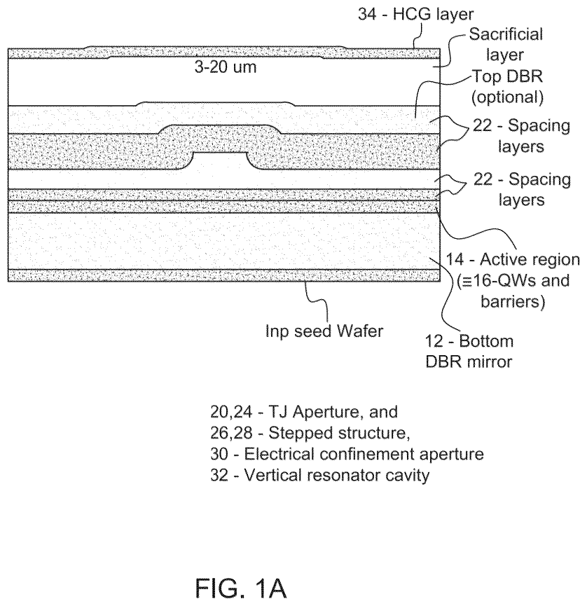

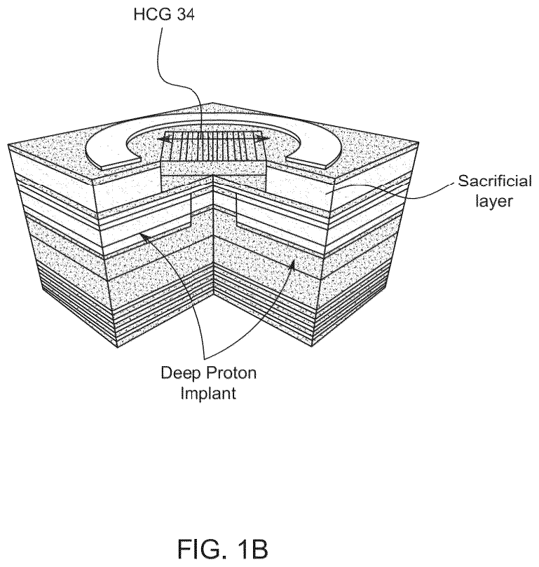

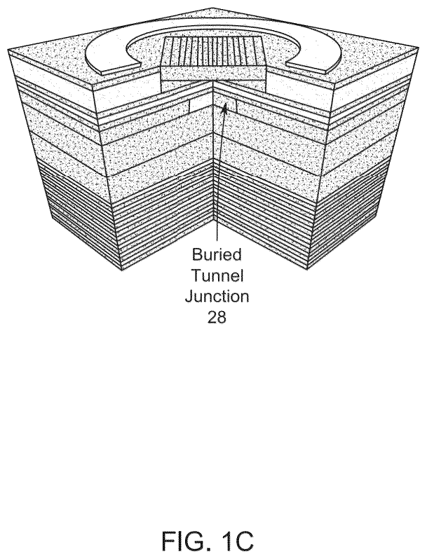

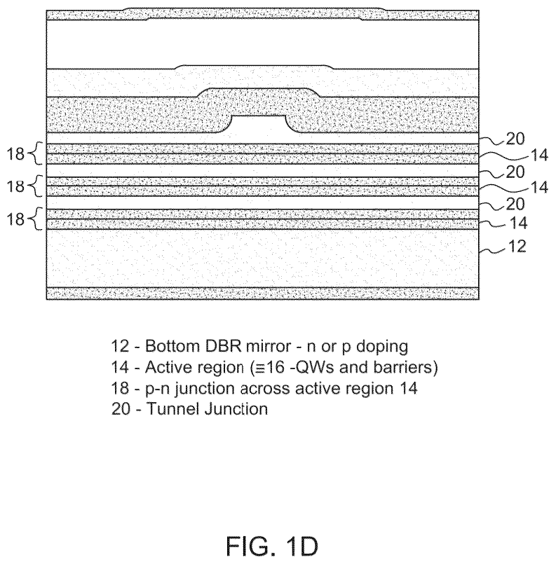

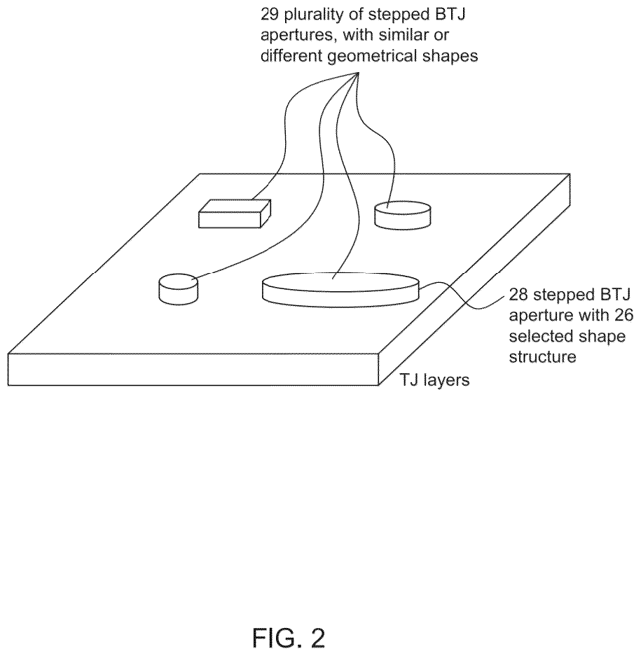

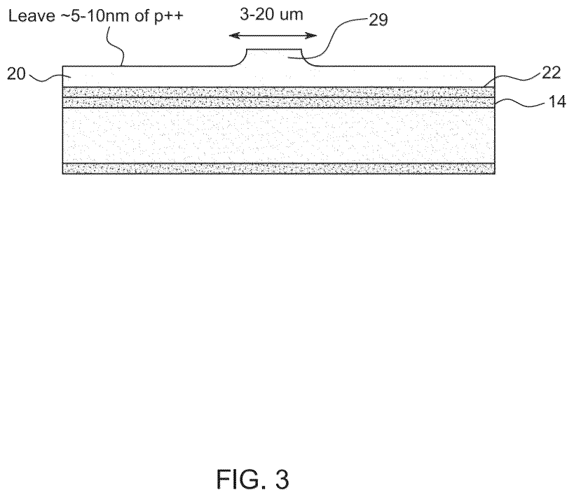

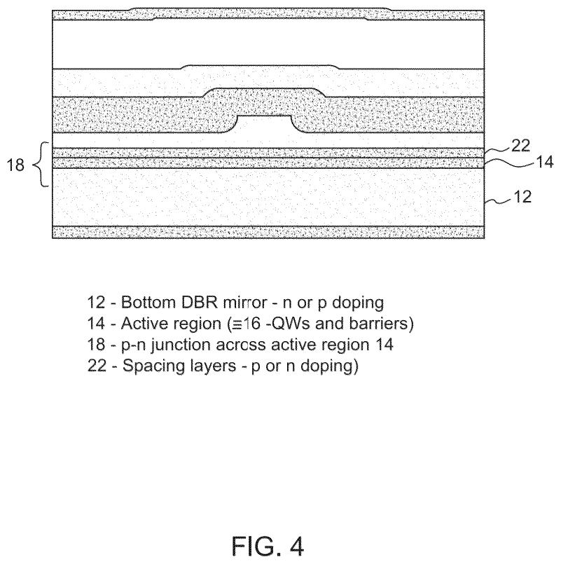

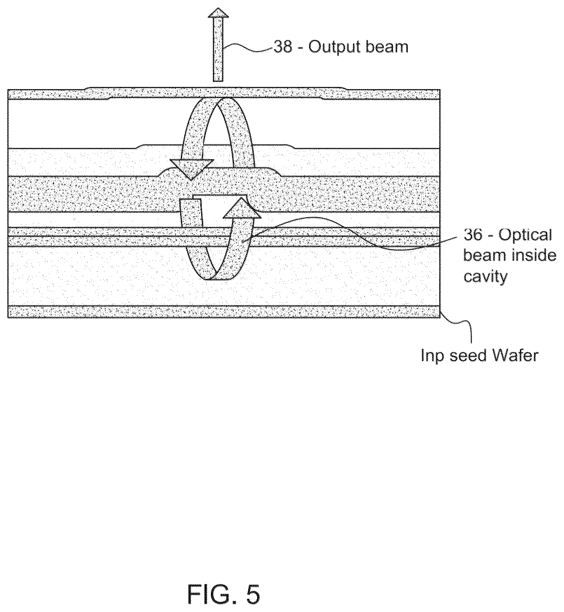

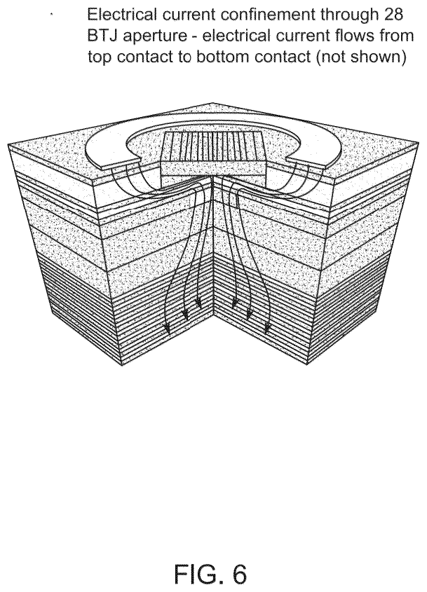

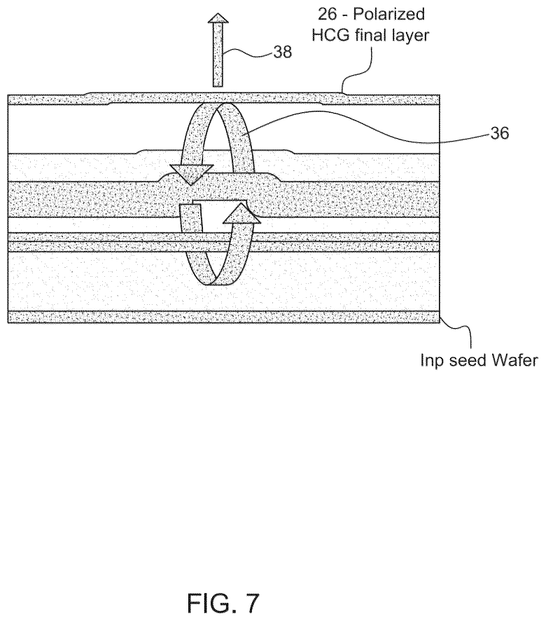

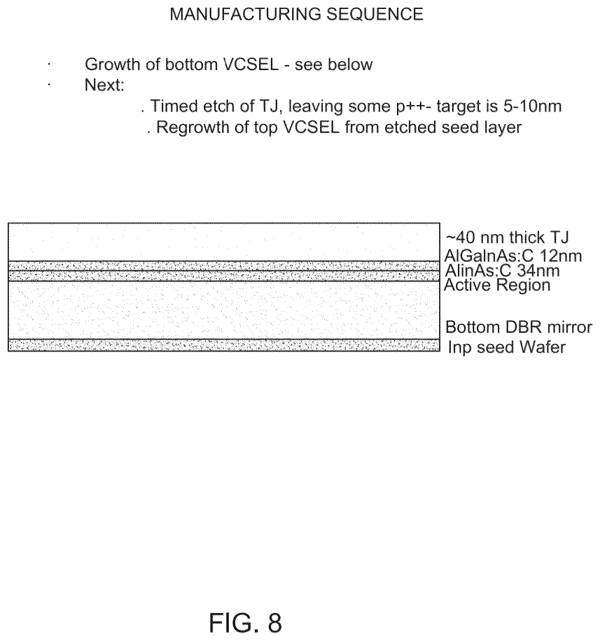

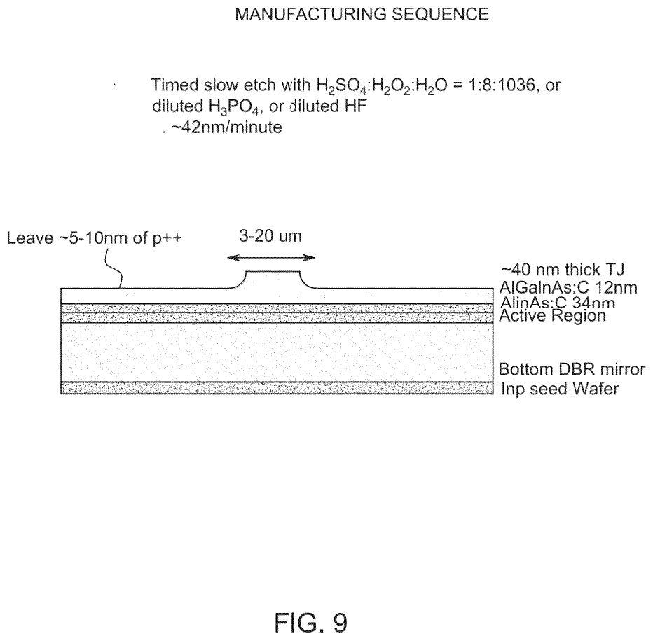

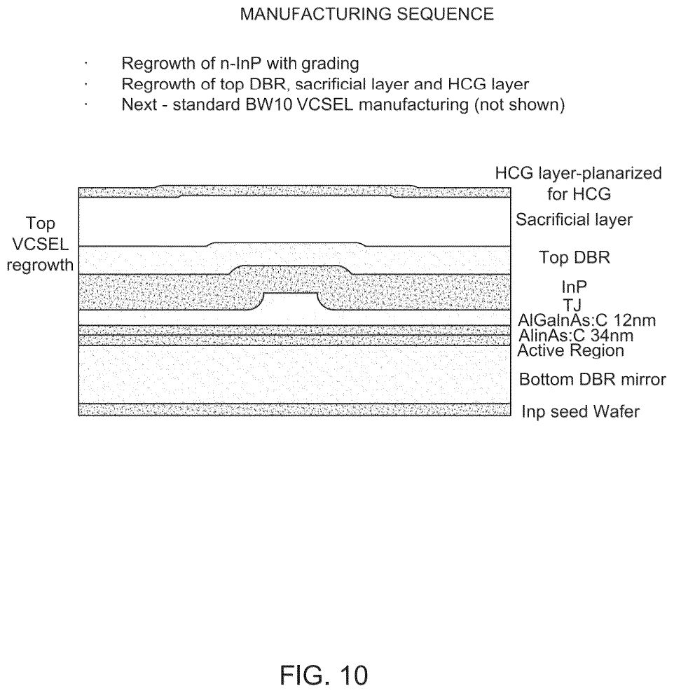

FIGS. 1-10 illustrates one embodiment of a VCSEL of the present invention.

In one embodiment, VCSEL 10 includes an etched post 110. This provides advantages of very small volume and very tight current (delimited by the etched post 110 itself) and optical (delimited by the air/post interface) confinement.

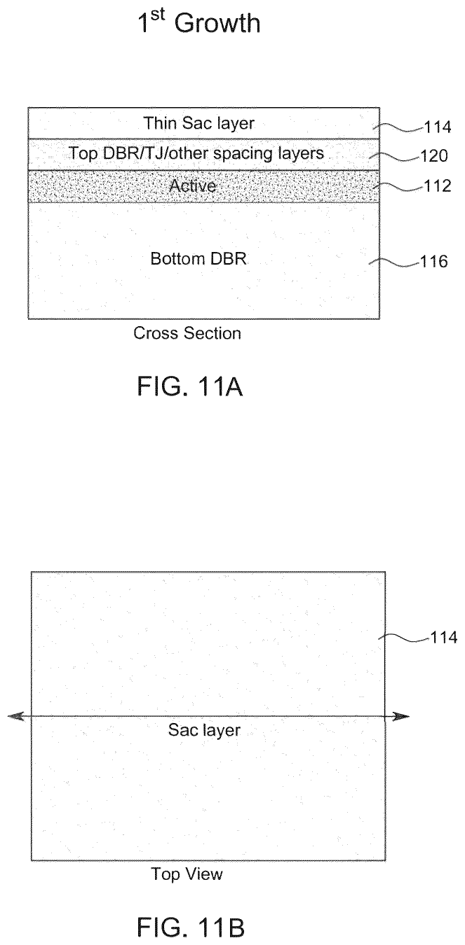

FIGS. 11A and 11B illustrate various embodiments of the etched post 110 of the present invention,

In one embodiment a regular VCSEL 10 epitaxial structure includes an etched post 110 between an active region 112 and a sacrificial layer 114. FIGS. 11A and 11B illustrate a first regrowth including a bottom DBR 116, active layer (region) 112, top DBR 118/other spacing layers 120. The sacrificial layer 114 has a thickness now greater than 100 nm. The optical confinement is defined by the etched post 110 which acts as a waveguide

The etched post 110 and regrowth provide lateral current and optical confinement, small volume and increased efficiency for more demanding applications, such as very high-speed modulation and coherent communication. The increased efficiency is achieved because the optical wave and the lateral currents overlap.

Instead of etching the post 110 for confinement in the optical path via mesa etch and regrowth, the optical path is preserved and modify its boundaries for optical confinement. The existence of the sacrificial layer 114 in the present invention favors this new approach as the final interface of regrown material in the optical path is etched away. This preserves optical quality. As a non-limiting example, the manufacturing requires integration and compatibility of several different processes, not required for the conventional semiconductor as-grown DBR.

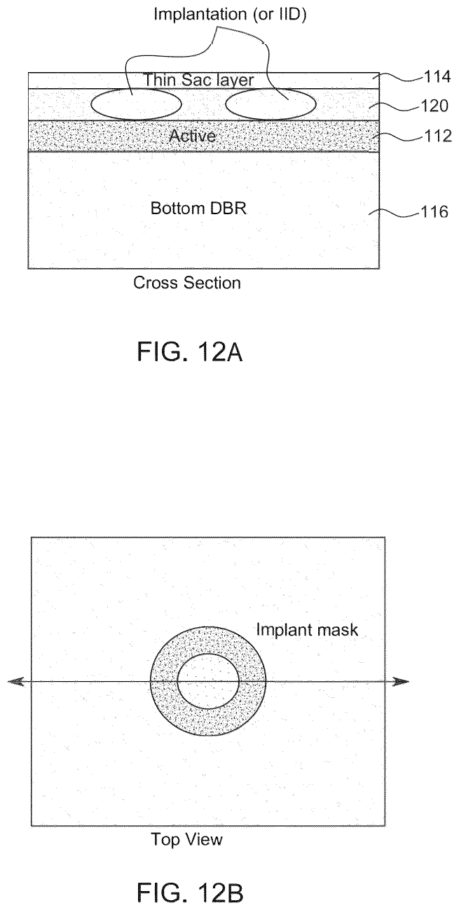

Regrowth of the sacrificial layer 114 around a small mesa 122 step brings much smaller complication when compared to previous approaches of buried heterostructures with steep walls more than 2× taller (3-4 um) than mesa 122 (0.8 um).In one embodiment, a full VCSEL is grown up to a thin SAC layer (100 nm of Al0.22Ga0.25In0.53As with 100 nm InP cap). As illustrated in FIGS. 12A and 12B implantation is then proceeded for current confinement under the metal contact pads. FIG. 12 illustrates the etched post 110.

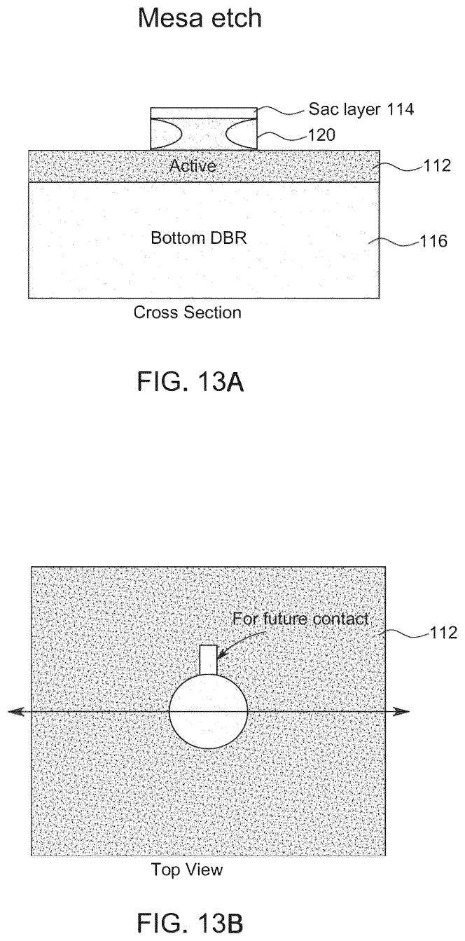

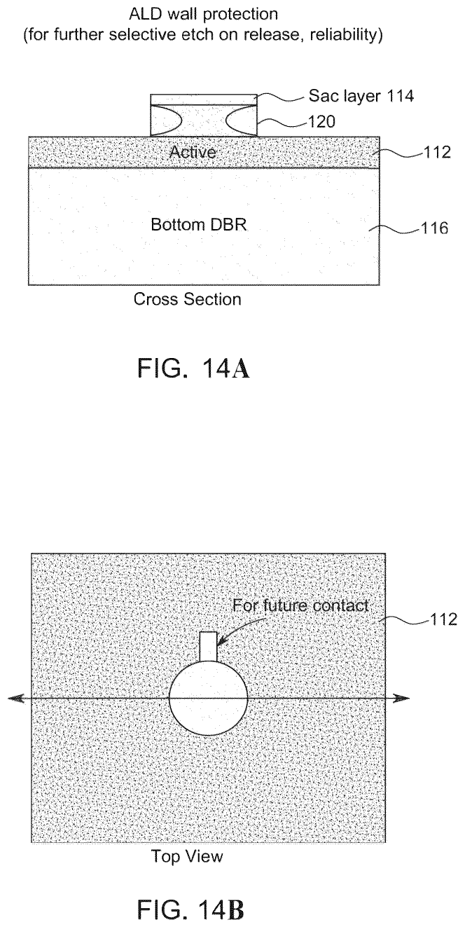

In one embodiment, implantation is done on a structure with the bottom DBR 116, active layer 112 and a thin sacrificial layer 114. The implantation is done on a layer between the active layer 112, and the sacrificial layer 114. An implant mask is used. The structure, including the bottom DBR 116, active layer 112, sacrificial layer 114 and mesa 122 position therebetween, is then dry etch down a very tiny mesa 122 for high-speed (radius of 5-10 um), up to InP layers, close to a TJ interface FIGS. 13A and 13B. The mesa 122 having an increasing radius up to a top layer. Optical monitoring can be used. Referring to FIGS. 14A and 14B, atomic layer deposition (ALD) is performed only on side walls of etched post 110. This protects the etched post 110 from further release, increased reliability and isolation from surrounding air.

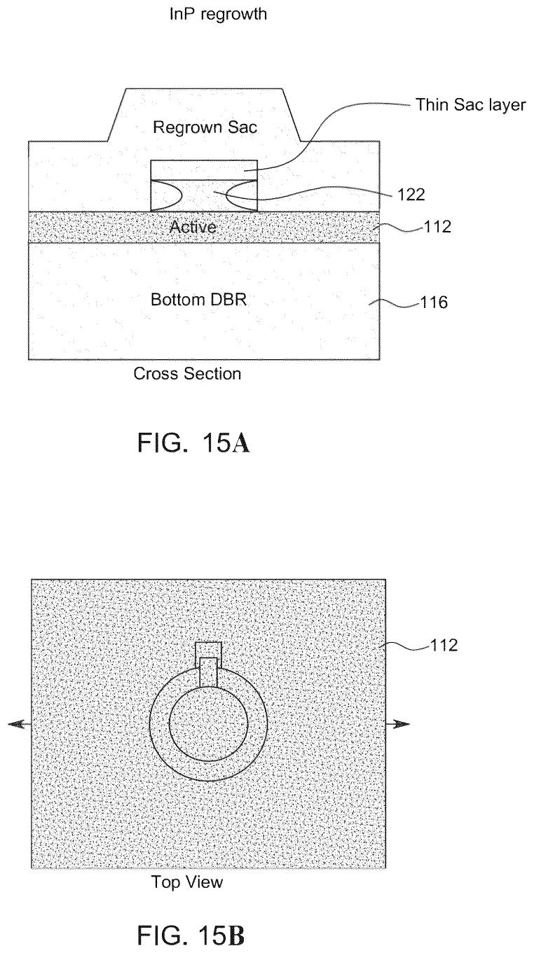

In one embodiment, illustrated in FIGS. 15A and 15B, ALD wall protection is used for further selective etch on release, and for reliability.

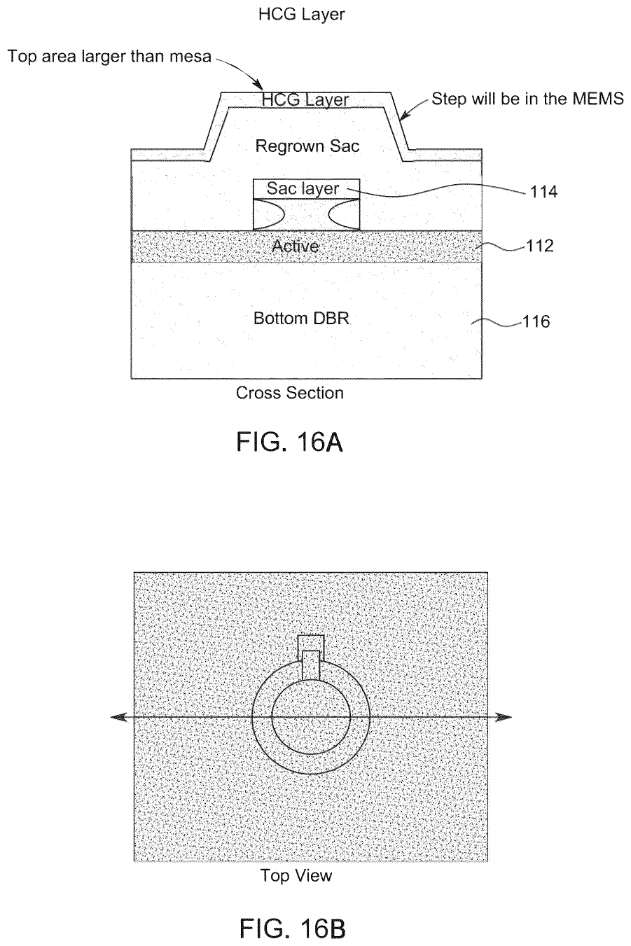

A full regrowth of a full sac layer+HCG on top is performed, as illustrated in FIGS. 16A and 16B, with the interface etched away. InP regrowth is a regrowth around the etched post 110. This is later removed, along with the sacrificial layer 114.

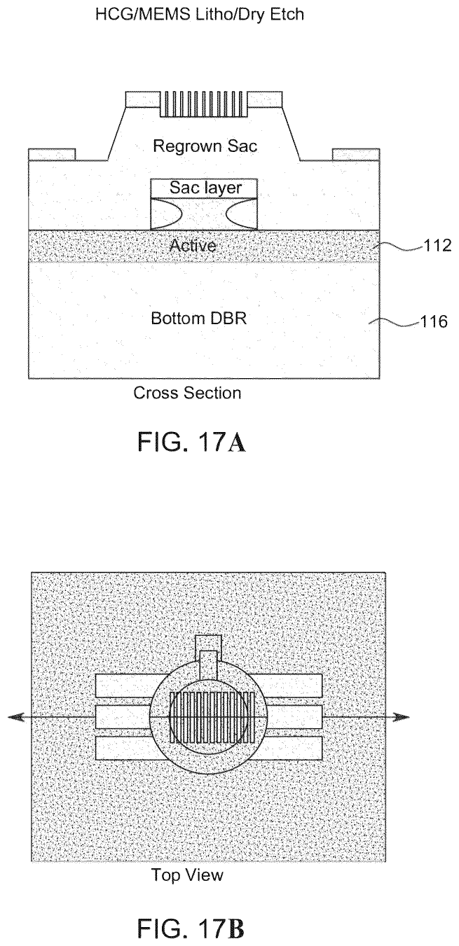

The regrowth interface is out of the optical/current paths. In one embodiment, the regrown layer, the new growing layers cause some defects on the crystal before arriving at the HCG layer. The structure includes the bottom DBR 116, active region (layer) 112, a thin sacrificial layer 114, a mesa 122 therebetween, and a regrowth sacrificial layer 114. In one embodiment, the mesa 122 grows laterally during regrowth for a slightly bigger than mesa 122 HCG, FIGS. 17A and 17B As a non-limiting example, a vertical step on the MEMS beams is not a problem. There is no need for implantation confinement.

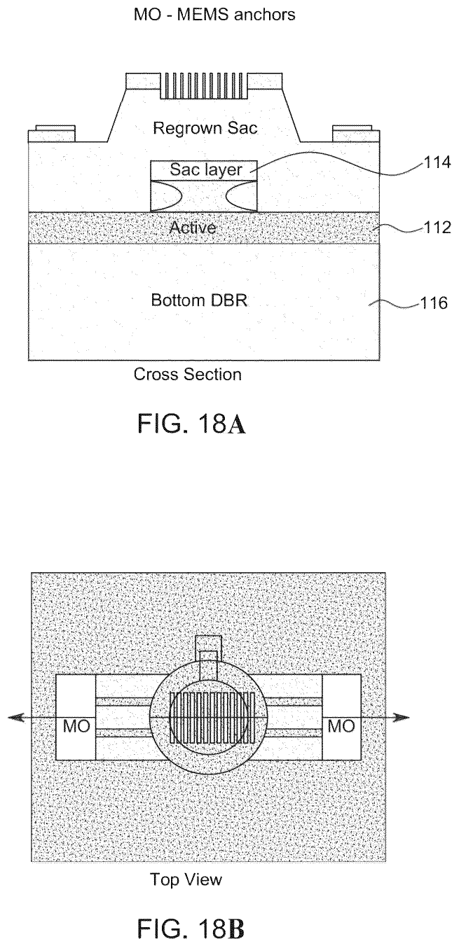

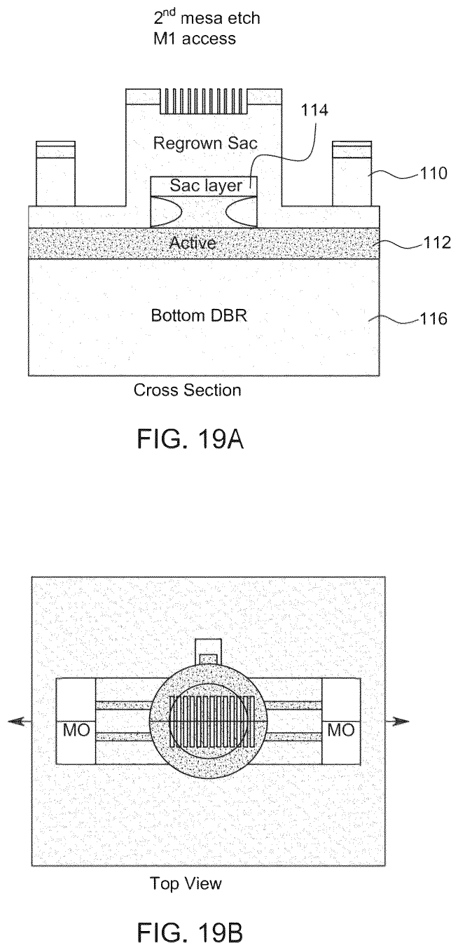

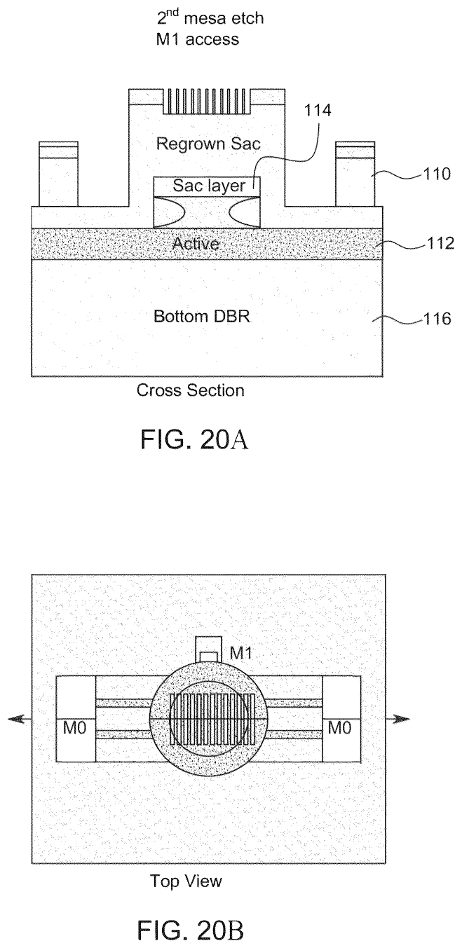

In one embodiment, mesa 122 confinement is provided, e.g, implantation is required only for contact isolation and current injection from the top of the mesa 122. In one embodiment, normal processing is completed for adding contact pads, which as a non-limiting example, the contact pads can be metal 3 and polyimide. MEMS anchors are on either side of the mesa 122, FIGS. 18A and 18B. In one embodiment, a second mesa etch is provides, FIGS. 19A and 19B, following by an MI cut, FIGS. 20A and 20B.

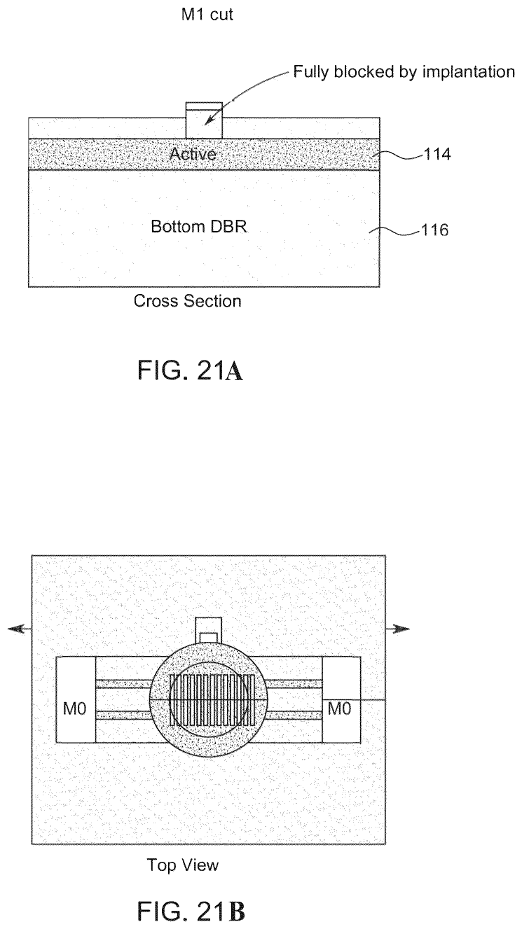

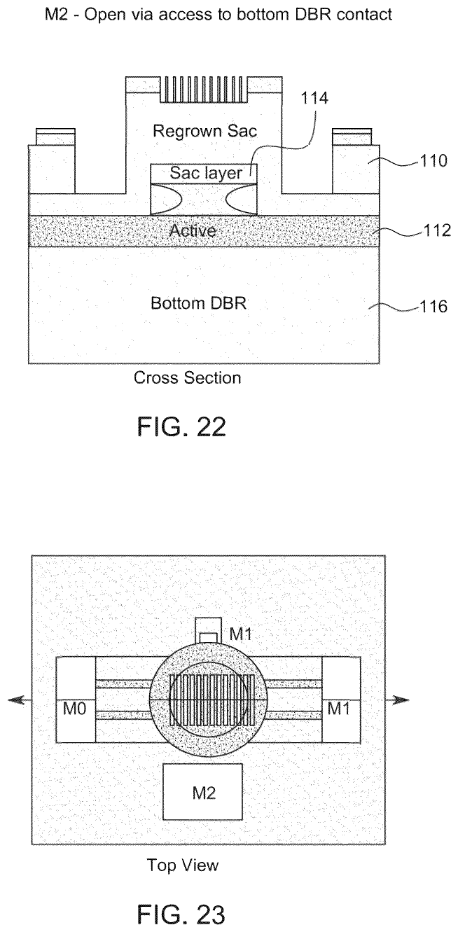

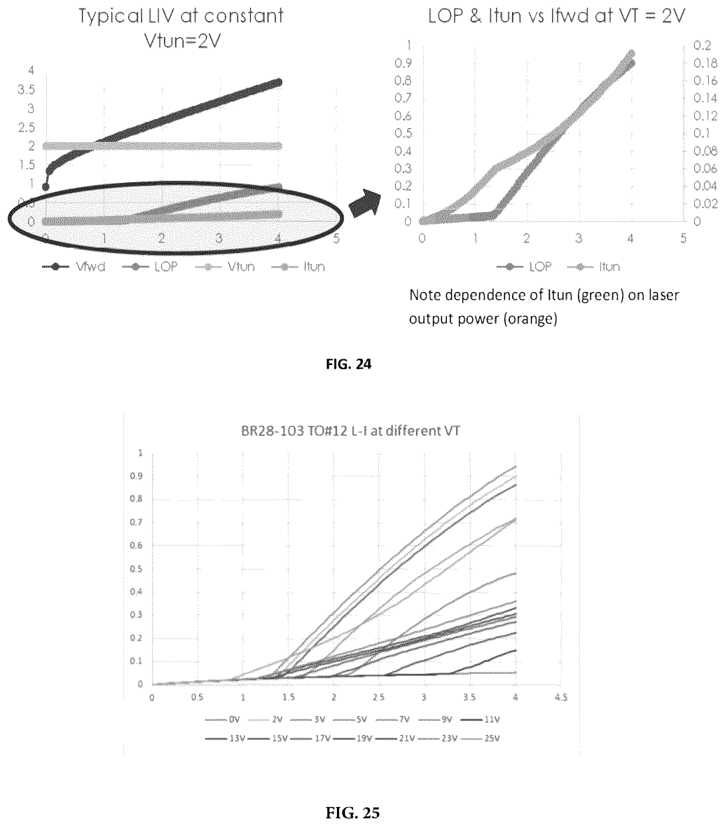

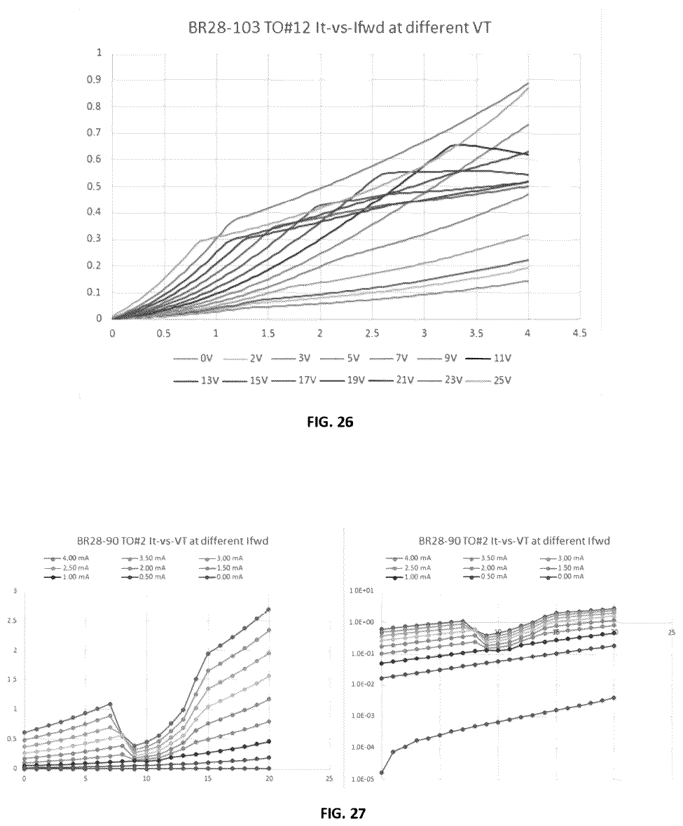

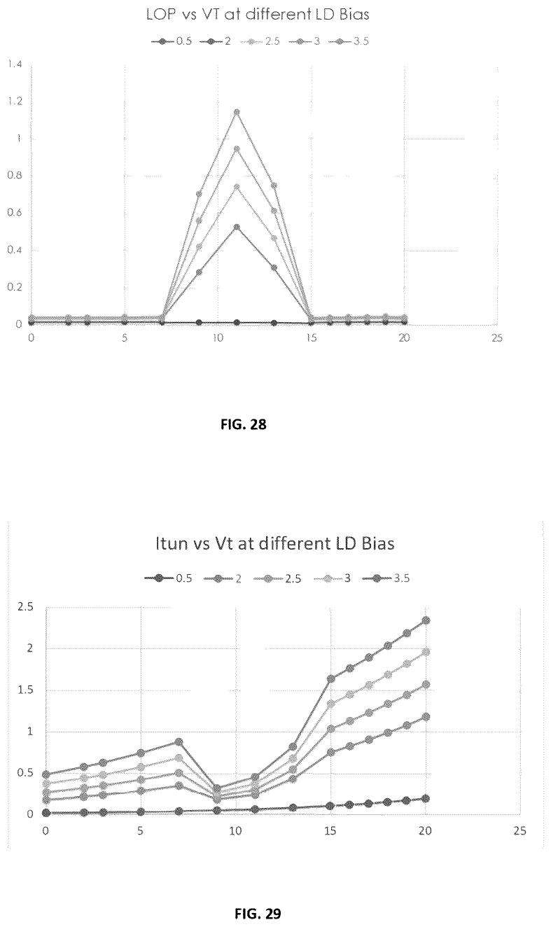

An opened access, M2, to the bottom DBR 116 contact is created, FIGS. 21A and 21B. This is followed by a release, FIGS. 22. As shown in FIGS. 23, the release includes can be at the MEMS beams.

E-beam lithography has some topography on the MEMS beams. The beams can be defined by regular lithography (1-2 um wide).

### EXAMPLES

### EXPERIMENTAL DATA

Tunable HCG VCSEL uses the parameter Vtun (tuning voltage) to control lasing wavelength
Vtun—tuning voltage, applied across HCG layer and bottom of sacrificial layer
Standard VCSEL parameters are
LOP—Laser Output Power
Ifwd—VCSEL electrical pumping current
Vfwd—VCSEL voltage (voltage across laser)
Detector Current
Itun—measured in between HCG layer and bottom of sacrificial layer (same terminals as Vtun)
Different wavelengths, at different Vtun, have different inclination and threshold current (top graph)
Itun always change inclination and has a kink at laser threshold for each different wavelength (bottom graph)
for Ifwd≲1 mA, there is no lasing and Itun x Vtun is approximately linear
for Ifwd>1 mA, VCSEL starts lasing and Itun follows laser power

Above graphs show that VCSEL is not lasing at all different Vtun. In other words, VCSEL is only lasing within a defined spectral range. For example, at Ifwd=4 mA (dark blue) VCSEL starts lasing at Vtun=7 mA and stops lasing above Vtun=15V. Note that Itun×Vtun is linear below 7V and above 15V.
note that for Ifwd=0 mA, I tun is ˜100× smaller than in a case where there is only spontaneous emission and VCSEL is not lasing yet (e.g., at Ifwd=0.5 mA)

It is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A VCSEL epitaxial structure, comprising:
an etched post between an active region and a sacrificial layer;
a regrowth of sacrificial layer and HCG layer around the etched post. providing a fully epitaxial grown tunable VCSEL with a cavity volume no greater than 50 cubic micrometers, lateral electrical current and optical confinement; and
wherein the etched post and regrowth provide lateral current and optical confinement, cavity volume small volume and an increased efficiency for applications of the VCSEL epitaxial structure.

2. The VCSEL of claim 1, wherein current flows through the etched post.

3. The VCSEL of claim 1, wherein optical confinement is defined by the post which acts as a waveguide.

4. The VCSEL of claim 1, wherein the VCSEL is made with a first regrowth including a bottom DBR, active layer, top DBR/other spacing layers, and a sacrificial layer with a thickness now greater than 100 nm.

5. The VCSEL of claim 5, wherein the VCSEL is made with a regrowth of the sacrificial layer and the HCG layer is created around the etched post.

6. The VCSEL of claim 1, wherein the etched post provides for increased efficiency because the optical wave and the lateral currents overlap.

7. The VCSEL of claim 1, wherein an optical path is preserved.

8. The VCSEL of claim 1, wherein the sacrificial layer is around a small mesa step

9. The VCSEL of claim 6, wherein ion implantation is done on a structure with a bottom DBR, active, and a thin sacrificial layer.

10. The VCSEL of claim 10, wherein the implantation is done on a layer between the active layer, and a thin sacrificial layer.

11. The VCSEL of claim 11, wherein atomic layer deposition (ALD) is performed on side walls of the etched post.

12. The VCSEL of claim 12, wherein ALD wall protection is used for further selective etching on release, and for reliability, the ALD wall providing isolation from surrounding air.

13. The VCSEL of claim 1, wherein a full regrowth of a full sacrificial layer and HCG on top is performed.

14. The VCSEL of claim 14, wherein an interface is etched away and a regrowth is provided around the etched post.

15. The VCSEL of claim 15, wherein a regrowth interface is out of optical/current paths.

16. The VCSEL of claim 16, wherein the regrown layer is thick enough for relaxing defects before arriving at the HCG layer.

17. The VCSEL of claim 17, wherein a mesa grows laterally during regrowth.

18. The VCSEL of claim 18, wherein mesa confinement is provided.
